(19) United States
(12) Patent Application Publication
(10) Pub. No.: US 2009/0009368 A1
(43) Pub. Date: Jan. 8, 2009

(54) INPUT DEVICE, AND MOBILE TERMINAL HAVING THE SAME

(76) Inventors: Shinichi Takasaki, Osaka (JP); Hiroshi Yamamoto, Osaka (JP); Shigeyuki Inoue, Kyoto (JP); Takako Shiraishi, Nara (JP)

Correspondence Address: SINTEK INDUSTRIES, 647 E. E ST., SUITE 102, ONTARIO, CA, 91764, US

(21) Appl. No.: 11/817,430

(22) PCT Filed: Mar. 16, 2006
(86) PCT No.: PCT/JP2006/305254

§ 371 Date: Aug. 30, 2007

(30) Foreign Application Priority Data
Mar. 29, 2005 (JP) 2005-096146

(51) Int. Cl. H03K 17/94

(52) U.S. Cl. 341/22

(57) ABSTRACT

Provided is an input device that does not allow an input efficiency to be drastically lowered even when the number of pressing a key falls.

The input device of the present invention comprises the following: an input key (9) which has predetermined sections on each of which predetermined character-related information and the like are displayed; an association storage unit (71) that associates the predetermined sections of the input key (9) with the predetermined character-related information and the like; a section detection unit (70) that detects which section of the input key (9) is touched by an object; a selection unit (72) that selects, from among the information stored in the association storage unit (71), information that is associated with a section detected by the section detection unit (70), as input information; a press detection unit (74) that detects that the input key (9) is pressed or released from being pressed; and a determination unit (75) that determines the information selected by the selection unit (72) as the input information, when the press detection unit (74) detects that the input key (9) is pressed or released from being pressed.

### TECHNICAL FIELD

The present invention relates to an input device for inputting information, and particularly to a technique for easily operating a mobile terminal having the input device.

### BACKGROUND ART

FIG. 1 is an external view of a conventional mobile terminal. As shown in FIG. 1, a conventional mobile terminal 100 includes a built-in operation unit 101 as an input device in addition to a display unit 102, a speaker 103, and a microphone 104.

Moreover, the operation unit 101 of the mobile terminal is provided with input keys, function keys, selections keys, and an enter key. The input keys include twelve kinds of keys which are: ten numeric keys on which numerals 0 to 9 are respectively labeled; and two other keys on which * and # are respectively labeled. The function keys are used for calling functions, such as “clear,” “memo,” and “manner mode.” When a user of the mobile terminal operates the mobile terminal with a hand, the user typically holds the mobile terminal in one hand and operates the input keys, the function keys, the selections keys, and the enter key with the thumb of the hand holding the mobile terminal.

The conventional mobile terminal is not designed to facilitate an input operation for characters, numerals, symbols, and the like. For example, in the case where the user inputs [symbol] the user needs to go through four steps: press a key labeled 1 five times to input in the order corresponding to [symbol] then press a key labeled 6 once to input [symbol] subsequently press a key labeled 8 three times to input in the order corresponding to [symbol] and lastly press the key labeled 1 three times to input in the order corresponding to [symbol] . In other words, the user needs a key operation ten times in total to input four-character

[symbol]

[symbol]

FIG. 2 is a view depicting a load put on a user's thumb during an operation of the conventional mobile terminal. The keys provided for the conventional mobile terminal are not arranged in consideration of a region which allows for easy movement of a user's finger used for operation. That is to say, although the load put on the thumb is relatively light when operating the keys in a region A apart from the base of the thumb, a heavy load is put on the thumb when operating the keys in a region B close to the base of the thumb. As a result, the more the number of key operations is, the heavier the load is put on the hand and the finger used for operation, which can cause mental and physical fatigue. In addition, in the case where the fatigue has built up on the hand and the finger used for operation, the mobile terminal may be dropped and damaged when changing a hold on the mobile terminal.

This problem has remarkably arisen as the number of key operations has been increased along with multi-functionality of the mobile terminal in recent years. Especially in terms of character input operations such as e-mail creation, an increase in the number of characters allowed in an e-mail transmission has resulted in a significant increase in the number of key operations. For this reason, it is highly possible to cause the mental and physical fatigue, and this problem thus should be solved as soon as possible. Accordingly, a technique that lightens, by decreasing the number of key operations, the load put on the user during the operation of the mobile terminal has been proposed (see Patent Reference 1, for example).

FIG. 3 is a view showing an information processing device according to Patent Reference 1. This information processing device includes a display screen 200 and a keyboard 201L/R. Plural buttons 210L/R with a built-in touch sensor are arranged on the keyboard, and a function for inputting a numeric value or a character is assigned to each button. Information on the function assigned to each button is shown as a soft keyboard 300 on the display screen. When a button 210 L/R on the keyboard is touched by a user's thumb, the touch sensor detects this and makes only a soft button corresponding to the detected button be highlighted on the screen. With the soft button highlighted, pressing the button 210 L/R allows a function assigned to this button to be selected. As described above, according to a configuration in which one character is assigned to each button, it is possible to decrease the number of key operations and to lighten the load put on the user during the operation.

FIG. 4 is a view illustratively showing other keyboard (keypad) 820 according to Patent Reference 1. As shown in FIG. 4, the keyboard 820 includes a tactile feedback generation device 821, a pressure sensor 822, and a finger-position sensor 823. The finger-position sensor 823 detects a contact position of a user's finger. With the contact position of the finger detected, the pressure sensor 822 detects whether or not the keyboard is pressed with more than a predetermined pressure. The tactile feedback generation device 821 is a piezo actuator or an oscillatory actuator. In the case where the pressure sensor 822 detects a pressure more than the predetermined pressure, the tactile feedback generation device judges that a finger position detected by the finger-position sensor 823 is pressed and gives the user a sense of click. This way, it is possible to assign different functions (commands) based on the contact position of the finger, and it is not necessary to provide the plural buttons for each command.
Patent Reference 1: Japanese Unexamined Patent Application Publication No. 2004-355606

### DISCLOSURE OF INVENTION

Problems that Invention is to Solve

However, when a user's finger touches any button arranged on the keyboard 201L/R of the information processing device according to Patent Reference 1, as a soft button corresponding to the button is to be highlighted, there is a problem that an input operation of the first character is troublesome. In other words, the user cannot know where a target soft button is located without touching any button. Consequently, initially touching any button among the plural buttons, the user checks a highlighted soft button. After that, in the case where the soft button is not a target soft button, the user needs to verify a relative position between the highlighted soft button and the target soft button, and to move the finger on the keyboard so that the target soft button is highlighted. Even if only inputting one character, the user needs to follow the above steps. In this case, an input efficiency is drastically lowered.

Furthermore, a configuration in which plural characters are assigned to one button is depicted in Patent Reference 1. However, according to this configuration, there is a problem that it is difficult for the user to recognize whether a character has been successfully inputted. In other words, although vibrating the tactile feedback generation device 821 is designed to notify the user that the character has been successfully inputted, it is difficult for the user to immediately recognize that the character has been successfully inputted until the user gets used to the degree of vibration. Moreover, it may be difficult for the elderly to perceive something vibrating at the tip of a finger. In this case, it is necessary to look at a display content shown in an input result display unit 120 below the soft keyboard 300 in order to check whether a target character is inputted after every input operation for one character. Accordingly, the input efficiency is drastically lowered.

As described above, according to the information processing device in Patent Reference 1, although the number of pressing a key falls, there is a case where the input efficiency is drastically lowered, and it is hard to say that a mental and physical load put on the user can be always lightened.

The present invention has an object of providing an input device that does not allow an input efficiency to be drastically lowered even if the number of pressing the key is decreased.

### Means to Solve the Problems

In order to achieve the above mentioned object, the input device of the present invention is an input device for inputting information, comprising: an input key of a push-type, which has predetermined sections on each of which one of predetermined character-related information and predetermined function information is displayed; an association storage unit operable to store each of the predetermined sections of the input key in association with one of the predetermined character-related information and the predetermined function information; a section detection unit operable to detect which section of the input key is touched by an object; a selection unit operable to select, from among the information stored in the association storage unit, information that is associated with the section detected by the section detection unit, as input information; a press detection unit operable to detect that the input key is pressed or released from being pressed; and a determination unit operable to determine the information selected by the selection unit as the input information, when the press detection unit detects that the input key is pressed or released from being pressed. Accordingly, since only sliding a user's finger on the input key enables the user to select target information from among plural pieces of information and pressing the input key once enables the user to determine the selected information, it is possible to reduce the number of pressing the input key. Moreover, since information assigned to each section of the input key is displayed, in the case where the user inputs a first character, the user can easily find an input key where the character is displayed. Furthermore, as the input key of the push-type is adopted for the input key, it is possible for the user to input a character and the like with a simple operation of pressing the input key. In other words, even if the number of pressing the input key is reduced, an input efficiency does not get drastically lowered unlike before.

In addition, the input device comprises a determined information storage unit operable to store the information determined by the determination unit. The selection unit may select, as the input information, the information stored in the determined information storage unit, when the input key is touched by the object. As a result, even if any section of any input key is touched by the user, the information determined in a previous operation can be selected initially.

The input device further comprises a selected information storage unit operable to store the information selected by the selection unit. The selection unit may select, as the input information, the information stored in the selected information storage unit, when the input key is touched by the object. As a result, even if any section of any input key is touched by the user, the information selected in a previous operation can be selected initially.

The input device further comprises a determined information storage unit, which is provided for each input key, operable to store the information determined by the determination unit. The selection unit may select, as the input information, the information stored in the determined information storage unit for the input key, when the input key is touched by the object. As a result, even if any section of an input key is touched by the user, the information determined in a previous operation can be selected initially with the input key.

The input device further comprises a selected information storage unit, which is provided for each input key, operable to store the information determined by the selection unit. The selection unit may select, as the input information, the information stored in the selected information storage unit for the input key, when the input key is touched by the object. As a result, even if any section of an input key is touched by the user, the information determined in a previous operation can be selected initially with the input key.

The selection unit may select, as the input information, information associated with a section having the largest touched area among sections detected by the section detection unit, when the section detection unit detects plural sections. Consequently, even if a section other than a target section is touched by the user, since the information associated with the target section can be selected, it is not necessary for the user to be careful in avoiding other sections as well as in touching a specific section.

The section detection unit may notify the selection unit of the section having the largest touched area when the section detection unit detects the plural sections. Consequently, it is possible to obtain the same effects as above. That is to say, even if a section other than the target section is touched by the user, since the information associated with the target section can be selected, it is not necessary for the user to be careful in avoiding other sections as well as in touching a specific section.

The input device may further comprise a change unit operable to change the information stored in the association storage unit. As a result, for example, a hiragana character and a katakana character can be mutually changed, and it is possible to associate a limited section with more information.

The larger the number of times information is determined by the determination unit, the more the change unit increases an area of a section to be associated with the information. As a result, the more the user uses the input device, the larger an area of a section associated with the information that the user frequently inputs is increased and the smaller an area of a section associated with the information that the user seldom inputs is decreased. This way, an input operation becomes simpler, and it is possible to set sections to suit user characteristics.

The number of the input keys may be plural. Accordingly, it is possible to arrange the plural input keys in accordance with a size of user's hand, a length of a user's finger, or user's preference. Furthermore, it is possible to associate a single input key with some pieces of relevant information and to associate different groups of information (e.g. the [symbol] row, the [symbol] row, and the like in the Japanese syllabary) with every input key. As a result, it is possible to arrange the input key in a manner that the user easily understands.

The input keys may be arranged in a m×n matrix. Accordingly, the user can reach a target input key by moving a user's finger used for operation vertically or horizontally to the input device, and select information by sliding the finger on the target input key. In other words, a combination of simple operations, such as moving the finger vertically or horizontally, enables the user to select target information. Moreover, the input keys being arranged in the same manner as a conventional mobile terminal, user-friendliness can be maintained.

The input keys may form a numeric keypad. Accordingly, each of the input keys can be associated with one numeral selected from numerals 0 to 9, and sliding the finger on the numeric keypad enables the user to select other information. Consequently, in the case where both a numeral and other information are inputted, it is possible to arrange the input key in a manner that the user easily understands.

The input keys may be arranged substantially parallel. That is to say, plural input keys being arranged linearly to the input device, in order to select an input key, the user only needs to move the finger either in a vertical direction or a horizontal direction to the input device. In order to select a character, the user only needs to slide the finger to the remaining selection.

The input keys may be arranged substantially in arc form. Accordingly, it is possible to arrange the input keys in accordance with a range of movement of a user's hand and finger, especially a range of movement of a user's thumb.

The change unit may associate one of plural sections arranged substantially linearly with the predetermined character-related information or the predetermined function information. Accordingly, a direction to which the user slides the finger is limited to a predetermined direction and its opposite direction (e.g. a right direction and a left direction), and the user does not need to mind sliding the finger to other directions (e.g. an upper direction and a lower direction).

The number of the input keys may be one. Accordingly, the user can select all the information on a single input key, thereby eliminating a time and an effort for moving the finger to other input key.

The association storage unit may associate one of plural sections substantially in a matrix with the predetermined character-related information or the predetermined function information. Accordingly, a single input key is divided into sections on a matrix, and a Japanese hiragana character, for example, can be arranged to each of the divided sections. As a result, since an input operation for hiragana characters that are often used in e-mail and the like can be performed with the single input key, it is possible to shorten a time for inputting Japanese.

Note that the present invention can be realized as such input device, as a mobile terminal including such input device, and as an input method having characteristic units included by such input device as steps.

### EFFECTS OF THE INVENTION

As is clear from the above description, according to the input device of the present invention, since only sliding a user's finger on an input key enables the user to select target information from among plural pieces of information and pressing the input key once enables the user to determine the selected information, it is possible to reduce the number of pressing the input key. Moreover, since information assigned to each section of the input key is displayed, in the case where the user inputs a first character, the user can easily find the input key displaying the character. Furthermore, as an input key of a push-type is adopted for the input key, it is possible for the user to input a character and the like with a simple operation of pressing the input key. In other words, even if the number of pressing the input key is reduced, an input efficiency does not get drastically lowered unlike before.

In addition, even if touching any section of the input key, the user can initially select the information determined previously with the input key. Consequently, in the case where the user wants to input information that is same as the information determined in the past, since only pressing the input key enables the user to determine the information and sliding the finger on the input key is not necessary, an operation load put on the user can be lightened.

Moreover, even if touching any section of the input key, the user can initially select the previously selected information. Accordingly, the user does not need to try an information search again, and a load put on the user is lightened.

Furthermore, in the case where plural sections are touched by the user, it is possible for the user to select target information. Since it is not necessary for the user to be careful in avoiding other sections as well as in touching a specific section, a frequency of incorrect input is reduced and an input operation time is shortened.

Additionally, since ranges of each section assigned on the input key are changed based on the number of times inputted in the past, it is possible to set the sections to suit the user characteristics.

### BRIEF DESCRIPTION OF DRAWINGS

FIG. 1 is an external view of a conventional mobile terminal.

FIG. 2 is a view depicting a load put on a user's thumb during an operation of the conventional mobile terminal.

FIG. 3 is a view of a conventional information processing device according to Patent Reference 1.

FIG. 4 is a view illustratively showing other keyboard according to Patent Reference 1.

FIG. 5 is an external view of a mobile terminal according to a first embodiment.

FIGS. 6A and 6B are function block diagrams of a chief part of an input device according to the first embodiment.

FIG. 7 is a conceptual association table stored in a association storage unit.

FIG. 8 is a view depicting a section detection unit and a press detection unit.

FIG. 9 is a diagram showing a configuration of the input device according to the first embodiment.

FIG. 10 is a pattern diagram of the structure of a publicly-known LCD push-button switch.

FIG. 11 is a flow chart showing operations of the input device according to the first embodiment.

FIGS. 12A, 12B, and 12C are views, and each of which shows an input operation by a user.

FIGS. 13A, 13B, and 13C are views, and each of which shows an input operation by a user.

FIGS. 14A, 14B, and 14C are views, and each of which shows an input operation by a user.

FIG. 15 is a view showing a status of display when plural sections are touched by a user.

FIG. 16 is a view showing a change of ranges of each section.

FIGS. 17A and 17B are views showing a change of information to be inputted.

FIGS. 18A, 18B, and 18C are views, and each of which shows an input operation by a user.

FIG. 19 is a chart showing transitions of information to be stored in a selected information storage unit and a determined information storage unit.

FIG. 20 is an external view of a mobile terminal according to a second embodiment.

FIG. 21 is a diagram showing a configuration of an input device according to the second embodiment.

FIG. 22 is a flow chart showing operations of the input device according to the second embodiment.

FIGS. 23A, 23B, and 23C are views, and each of which shows an input operation by a user.

FIGS. 24A, 24B, and 24C are views, and each of which shows an input operation by a user.

FIGS. 25A, 25B, and 25C are views, each of which shows an input operation by a user.

FIG. 26 is an external view of a mobile terminal according to a third embodiment.

FIG. 27 is a diagram showing a configuration of an input device according to the third embodiment.

FIG. 28 is an external view of a mobile terminal according to a fourth embodiment.

FIG. 29 is a diagram showing a configuration of an input device according to the fourth embodiment.

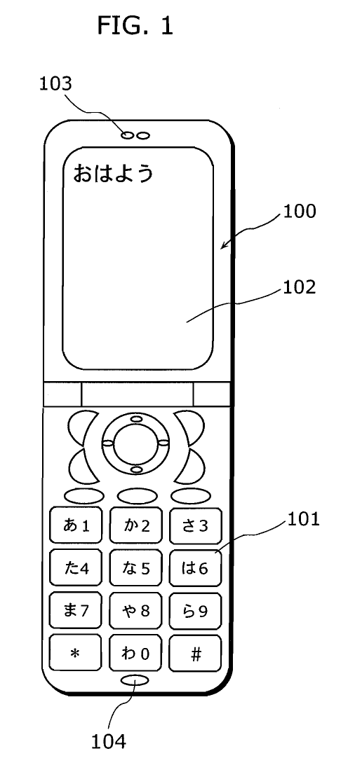

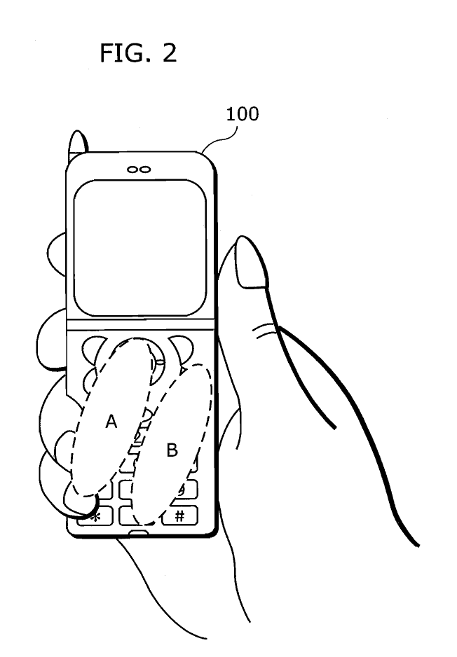

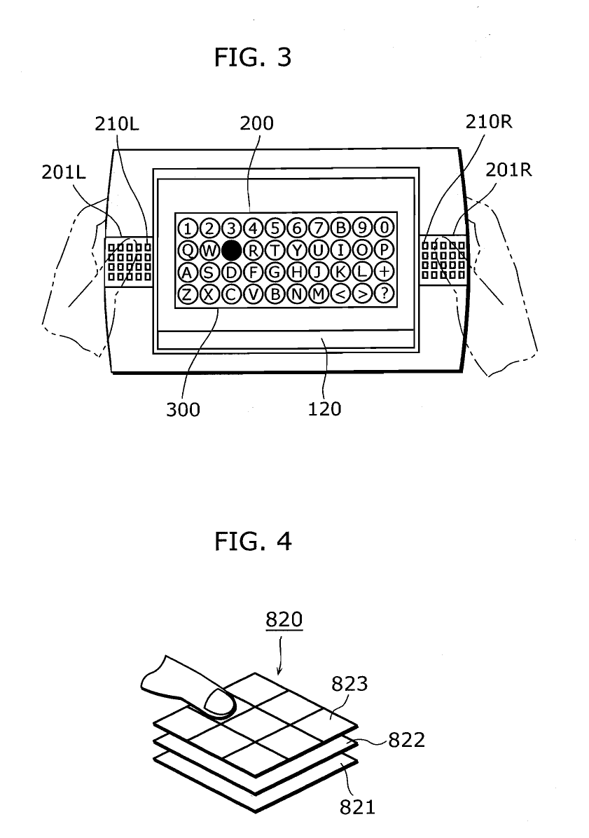

### NUMERICAL REFERENCES

1, 21, 41, 51 Input device
2 First chassis
3 Second chassis
4 Hinge
5 Antenna
6 Speaker
7 Display unit
8 Audio input unit
9, 29, 49, 59 Input key
10, 30, 50, 60 Section
11 Character conversion key
12 Enter key
13 Information input switch key
70 Section detection unit
71 Association storage unit
72 Selection unit
73 Selected information storage unit
74 Press detection unit
75 Determination unit
76 Determined information storage unit
100 Mobile terminal
101 Operation unit of conventional mobile terminal
102 Display unit of conventional mobile terminal
103 Speaker of conventional mobile terminal
104 Microphone of conventional mobile terminal
120 Input result display unit of information processing device in Patent Reference 1
200 Display screen of information processing device in Patent Reference 1
201L/R Keyboard of information processing device in Patent Reference 1
210L/R Buttons of information processing device in Patent Reference 1
300 Soft keyboard of information processing device in Patent Reference 1
820 Other keyboard of information processing device in Patent Reference 1
821 Tactile feedback generation unit of information processing device in Patent Reference 1
822 Pressure sensor of information processing device in Patent Reference 1
823 Finger-position sensor of information processing device in Patent Reference 1

### BEST MODE FOR CARRYING OUT THE INVENTION

The following describes preferred embodiments of the present invention with reference to drawings. Note that the same numerical reference is used for the same component in each of the following drawings.

### First Embodiment

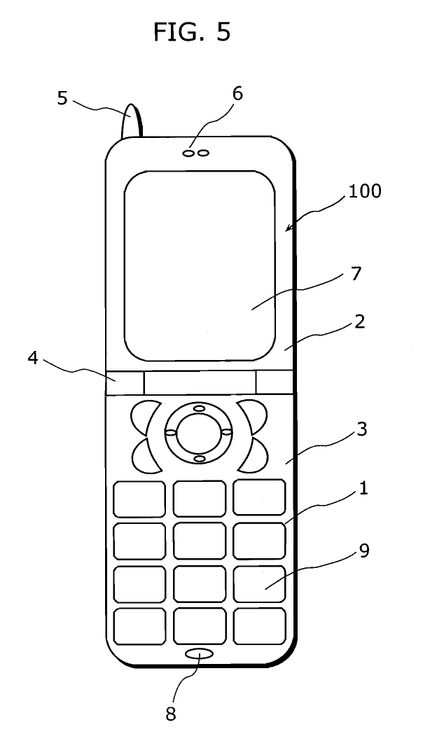

FIGS. 5 to 19 depict a first embodiment.

FIG. 5 is an external view of a mobile terminal which includes an input device 1 according to the first embodiment of the present invention. Including a first chassis 2 and a second chassis 3, the mobile terminal 100 is foldable. The first chassis 2 and the second chassis 3 are connected with a hinge 4. The first chassis 2 includes a speaker 6 that outputs audio and a display unit 7 that displays information inputted with the input device 1. The second chassis 3 includes the input device 1 which has an audio input unit 8 and plural input keys of a push-type 9. The top edge of the mobile terminal 100 is provided with an antenna 5. The mobile terminal 100 includes functions, such as making/having a phone call, receiving/sending an e-mail, connecting to the Internet and the like. However, since these functions are not the prime features of the present invention, a description of the functions is not given here.

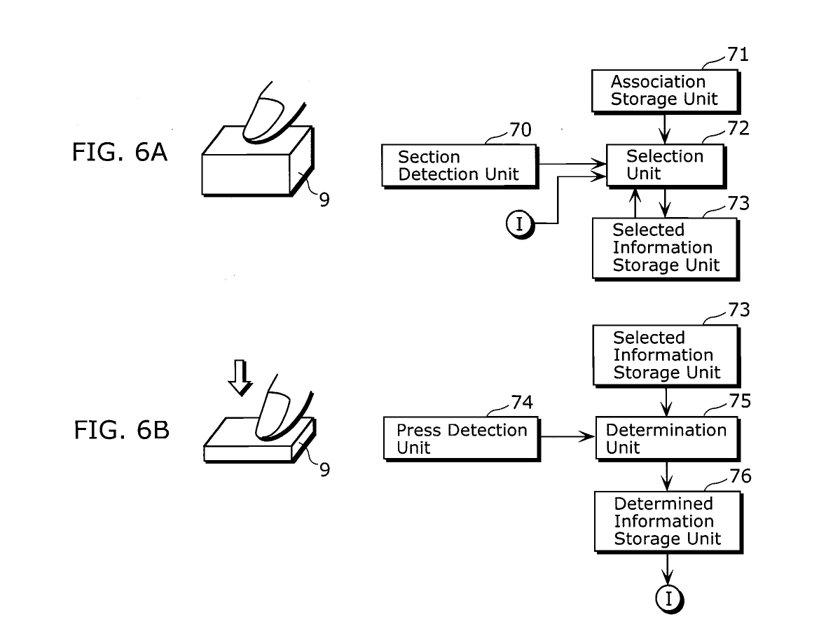

FIGS. 6A and 6B are function block diagrams of a chief part of an input device 1 according to the first embodiment of the present invention. The input device 1 is a device for inputting information, and includes an input key 9, a section detection unit 70, an association storage unit 71, a selection unit 72, a selected information storage unit 73, a press detection unit 74, a determination unit 75, and a determined information storage unit 76.

The selection unit 72 and the determination unit 75 can be, for example, realized when a CPU executes a program. The CPU for realizing the selection unit 72 and the determination unit 75 may be the identical CPU. Note that functions of the selection unit 72 and the determination unit 75 are described later.

The association storage unit 71, the selected information storage unit 73, and the determined information storage unit 76 can be, for example, realized with memorizing means such as a RAM. The memorizing means for realizing the storage units 71, 73, and 76 may be the identical memorizing means (the identical RAM and the like). Note that information to be stored in the storage units 71, 73, and 76 is described later.

As shown in FIG. 6A, the section detection unit 70 detects which section of the input key 9 is touched by an object. The association storage unit 71 stores predetermined sections of the input key 9 in association with predetermined character-related information or predetermined function information. The selection unit 72 selects, from among the information stored in the association storage unit 71, the information associated with the section detected by the section detection unit 70, as input information. The selected information storage unit 73 stores the information selected by the selection unit 72.

Note that the above mentioned character-related information is a generic term for characters, numerals, and symbols and that the function information relates to information concerning functions of the input device, such as “e-mail,” “web,” “setting,” and “camera.”

As shown in FIG. 6B, the press detection unit 74 detects that the input key 9 is pressed or released from being pressed. When the press detection unit 74 detects that the input key 9 is pressed or released from being pressed, the determination unit 75 determines the information stored in the selected information storage unit 73 as the input information. The determined information storage unit 76 stores the information determined by the determination unit 75.

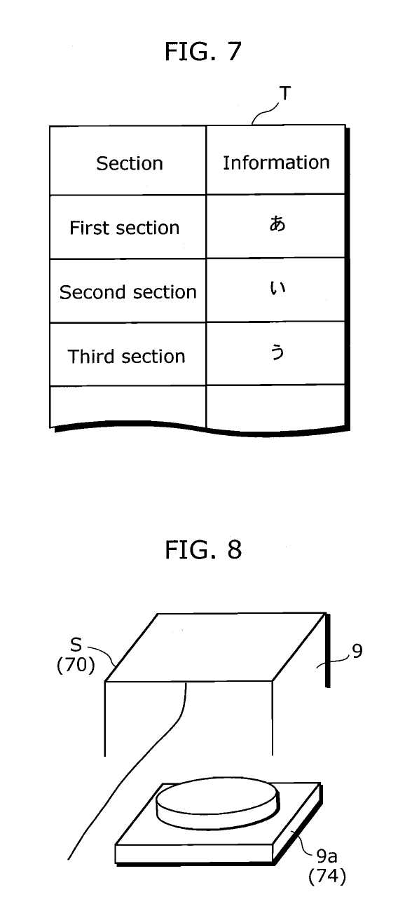

FIG. 7 is a conceptual association table T stored in the above mentioned association storage unit 71. That is to say, what it shows is that [symbol] is associated with a first section, [symbol] is associated with a second section, and [symbol] is associated with a third section. Although “a first section” is simply mentioned, what it means by a section is that a section corresponds to a surface of the input key 9 and may be expressed with a XY coordinate value and a coordinate value from a reference position.

FIG. 8 is a view depicting the section detection unit 70 and the press detection unit 74.

The section detection unit 70 is a means to detect which section of the input key 9 is touched by an object, and is specifically a capacitive touch sensor S provided on the input key 9. The capacitive touch sensor S generates an even electric field on the sensor surface as an even electric pressure is given to the four corners of the sensor. When the sensor surface is touched by a user's finger under this condition, since a change of capacitance that is proportional to a distance from the four corners of the sensor to the finger occurs, a coordinate position of the finger can be calculated in accordance with the change of capacitance at the four corners. Based on this principle, the section detection unit 70 specifies a section touched by the finger with a XY coordinate.

The press detection unit 74 is a means to detect that the input key 9 is pressed, and is specifically a key contact point 9a. In other words, the first embodiment adopts an input key of a push-type. The input key of the push-type is structurally a single physical key, and a key top of the input key of the push-type mechanically moves up and down.

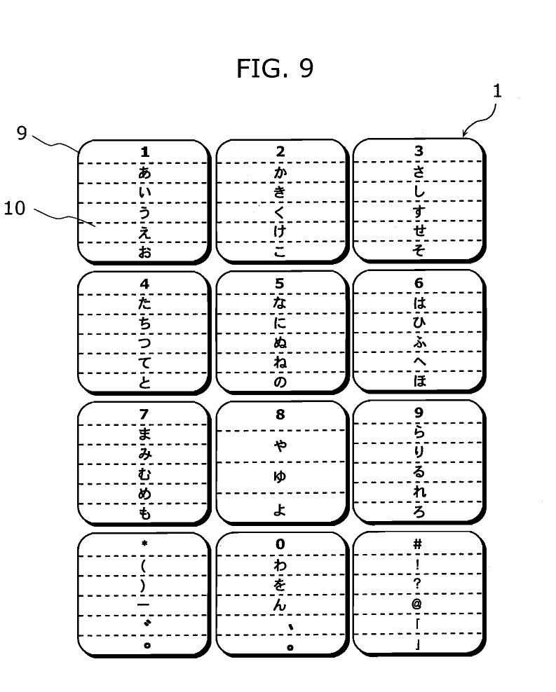

FIG. 9 is a diagram showing a configuration of the input device 1 according to the first embodiment. The input device 1 includes plural input keys 9, and these input keys 9 are arranged in a 3×4 matrix. Plural sections 10 are linearly assigned on each input key 9. One numeral selected from numerals 0 to 9 or two types of symbol “*” and “#” are assigned to the lead section 10, and information such as characters and symbols is assigned to the rest of the sections 10.

As described above, the predetermined character-related information or the predetermined function information is displayed on the predetermined sections of the input key 9. As a means to realize the display, a simple means such as print or inscription may be adopted. However, using a liquid crystal display (LCD) for the key top enables display content on the key top to be changed as necessary.

FIG. 10 is a pattern diagram of the structure of a publicly-known LCD push-button switch (Nihon Kaiheiki General Catalog 2003. December, 2002. Nihon Kaiheiki Ind. Co., Ltd. pg. 491. Figure. New Product IS). A 36 dots×24 dots (total 864 dots) wide viewing angle liquid is used for a push-button key top K, and the dots enable an image and a character to be displayed. It is assumed in the description that such LCD is provided for the key top of the input key 9 according to the first embodiment of the present invention.

Moreover, as mentioned before, the capacitive touch sensor S is provided on the input key 9. The touch sensor S can detect which section 10 on the input key 9 is touched by a user. That is to say, when the user slides a user's finger on any input key 9, the touch sensor S on the input key 9 is activated. As a result, the touch sensor S can detect which section of the input key 9 is selected by the user and select the detected section and associated information as input information.

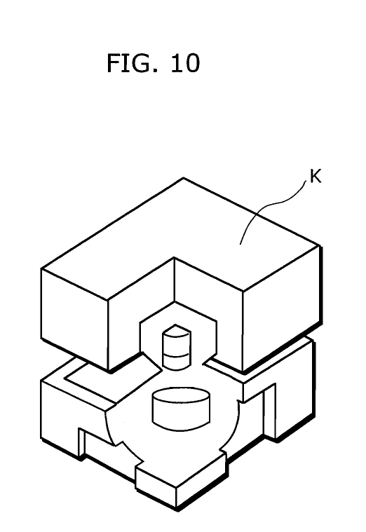

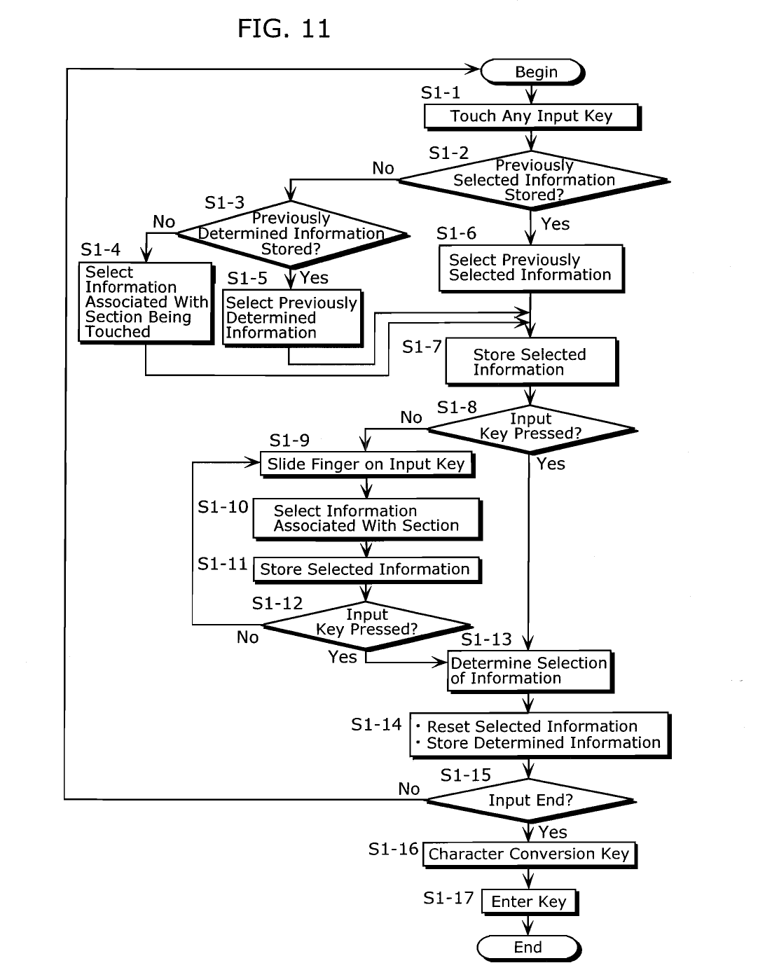

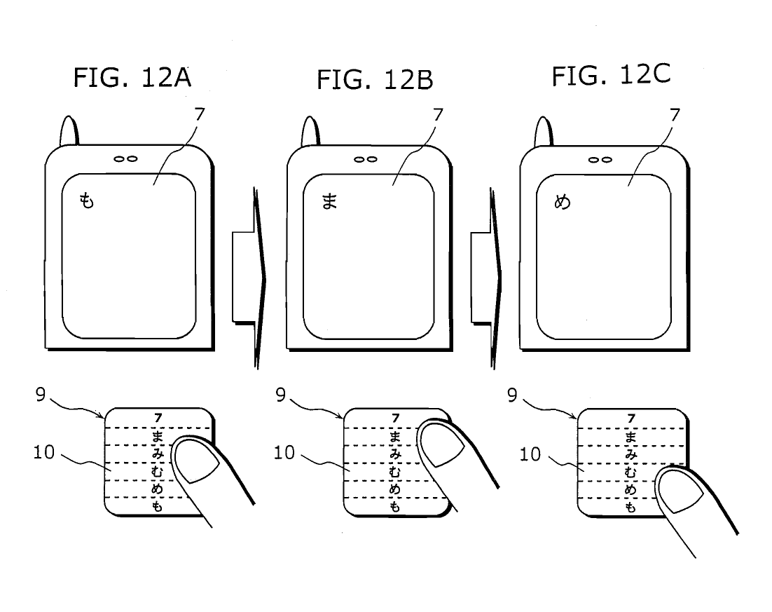

FIG. 11 is a flow chart showing operations of the input device 1 according to the first embodiment of the present invention. FIGS. 12A to 14C are views showing an input operation by a user, using a mobile terminal 100 which includes the input device 1 according to the first embodiment of the present invention, and an operation procedure compliant with the flow chart in FIG. 11.

Hereinafter, an operation of the input device 1 according to the first embodiment of the present invention is described with reference to FIGS. 11 to FIG. 14C. Note that the input device 1 includes, in addition to the input key 9, a character conversion key 11 which converts an inputted character into a Chinese character or a katakana character (the Japanese alphabet), an enter key 12 which enters an input, and an information input switch key 13 which switches a character to be inputted.

When any input key 9 is touched by the user (S1-1 in FIG. 11), the selection unit 72 determines whether information selected in a previous operation is stored in the selected information storage unit 73 (S1-2 in FIG. 11). “Information selected in a previous operation” is information selected by sliding a user's finger on the input key and denotes information not determined by pressing the input key 9. In other words, in the case where the user takes the finger off from the input key 9 in the middle of selecting information, information that is associated with a section touched right before the user takes the finger off is stored in the selected information storage unit 73.

With the selected information storage unit 73, even if any section of any input key 9 is touched by the user, the information selected in the previous operation can be selected initially. For this reason, the user does not need to try an information search again, which lightens a load put on the user. The description here proceeds on the assumption that information is not stored in the selected information storage unit 73 (S1-2: No in FIG. 11).

In the case where the information selected in the previous operation is not stored in the selected information storage unit 73, the selection unit 72 determines whether information determined in a previous operation is stored in the determined information storage unit 76 (S1-3 in FIG. 11). “Information determined in a previous operation” is information selected by sliding the finger on the input key 9 and denotes information determined by pressing the input key 9. That is to say, in the case where an input of information is determined by pressing the input key 9, the determined information is stored in the determined information storage unit 76.

As shown in FIG. 12A, in the case where a character determined in a previous operation is stored in the determined information storage unit (S1-3: Yes in FIG. 11), the character [symbol] determined at a previous time is selected by the selection unit 72 (S1-5 in FIG. 11), stored in the selected information storage unit 73 (S1-7 in FIG. 11), and additionally displayed on the display unit 7. At this time, in the case where the user wants to input the character [symbol] , it is possible to just press the input key 9 to determine the character [symbol] as input information (S1-8: Yes in FIG. 11).

With the determined information storage unit 76, even if any section of any input key 9 is touched by the user, the information determined in the previous operation can be selected initially. For this reason, the user does not need to slide a user's finger on the input key 9, which can lighten an operation load put on the user and shorten an input operation time.

Note that in the case where the information determined in the previous operation is not stored in the determined information storage unit 76 (S1-3: No in FIG. 11), information that is associated with a section touched by the user is selected by the selection unit 72 (S1-4 in FIG. 11), stored in the selected information storage unit 73 (S1-3 in FIG. 11), and additionally displayed on the display unit 7.

With the character [symbol] selected, as shown in FIG. 12B, when the user touches a section 10 of [symbol] assigned on the input key 9 (S1-9 in FIG. 11) without pressing the input key 9 (S1-8: No in FIG. 11), the character [symbol] is selected by the selection unit 72 (S1-10 in FIG. 11), stored in the selected information storage unit 73 (S1-11 in FIG. 11), and additionally displayed on the display unit 7.

In this condition, as shown in FIG. 12C, when the user slides the finger to other section (for example, the section of [symbol] without pressing the input key 9 (S1-12: No in FIG. 11), the character [symbol] is selected by the selection unit 72 (S1-10 in FIG. 11), stored in the selected information storage unit 73 (S1-11 in FIG. 11), and additionally displayed on the display unit 7.

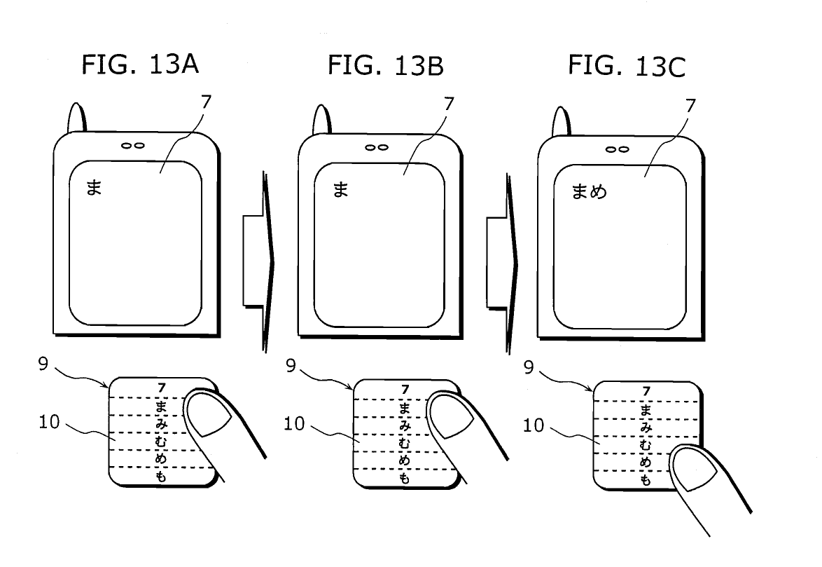

Furthermore, as shown in FIG. 13A, when the user presses the input key 9 while touching the section 10 to which the character [symbol] is assigned on the input key 9 (S1-8: Yes in FIG. 11), as shown in FIG. 13B, the character [symbol] is determined as input information (S1-13 in FIG. 11) and stored in the determined information storage unit 76 (S1-14 in FIG. 11). With the character [symbol] displayed on the display unit 7, an input of next information becomes possible.

At this time, the selection unit 72 deletes the information stored in the selected information storage unit 73 by resetting. Consequently, in the case where the user continuously inputs a character (S1-15: No in FIG. 11), when the user touches again the input key 9 with which an input has been determined in a previous operation (S1-1 in FIG. 11), the information determined in the previous operation is selected initially (S1-3 in FIG. 11) since the information is not stored in the selected information storage unit 73 (S1-2: No in FIG. 11). Therefore, the user can determine an input of information without sliding the finger on the input key 9, which can lighten an operation load and shorten an input operation time.

After the character [symbol] is determined, in the case where the user further continues an input of character with the same input key 9 without ending the input of character (S1-15: No in FIG. 11), the user slides the user's finger to the section to which the character [symbol] is assigned in that condition (S1-9 in FIG. 11). Accordingly, as shown in FIG. 13C, with the character [symbol] displayed on the display unit 7, the character [symbol] is selected by the selection unit 72 (S1-10 in FIG. 11), stored in the selected information storage unit 73 (S1-11 in FIG. 11), and additionally displayed on the display unit 7.

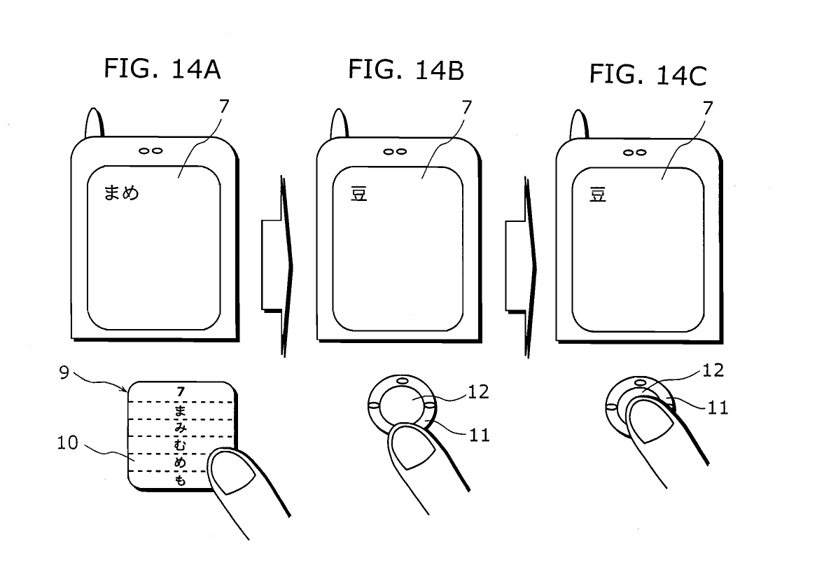

Moreover, as shown in FIG. 14A, with the character [symbol] displayed, when the user presses the input key 9 (S1-12: Yes in FIG. 11), the character [symbol] is determined as input information (S1-13 in FIG. 11) and stored in the determined information storage unit 76 (S1-14 in FIG. 11). In addition, characters [symbol] remain displayed on the display unit 7. In this condition, when the user ends an input of character (S1-15: Yes in FIG. 11) and presses the character conversion key 11 (S1-16 in FIG. 11) as shown in FIG. 14B, character conversion candidates of [symbol] are displayed. Consequently, when the user selects a desired character from among the character conversion candidates and presses the enter key 12 (S1-17 in FIG. 11) as shown in FIG. 14C, the input of character [symbol] gets completed.

As described above, only sliding the finger on the input key enables the user to reach the target information, and it becomes possible for the user to press the input key only once to determine the information as the input information.

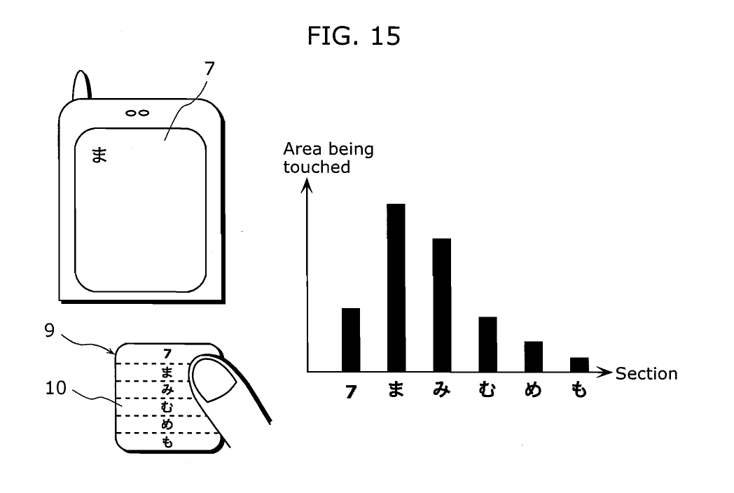

FIG. 15 is a view showing the display unit 7 displaying information to which one of the sections is assigned when a user touches plural sections 10 assigned on the input key 9. In other words, since much information is provided on the input key 9, it is conceivable that the larger a touched area is, a users' finger may touch across adjacent sections. The selection unit 72 calculates an area of section touched and selects information which is corresponded with a section having the largest area as input information. The information selected in this manner is stored in the selected information storage unit 73 and displayed on the display unit 7. Since the section to which [symbol] is assigned, among the sections 10 to which [symbol] and [symbol] are respectively assigned, is the section having the largest touched area, the character [symbol] is displayed on the display unit 7.

Note that although it has been described that the selection unit 72 calculates the area of section touched and selects the information which is associated with the section having the largest area as the input information, the present invention is not limited by this. That is to say, a touch sensor side, a section detection means, may detect a section having the largest touched area. Even if a configuration in which the touch sensor side detects the section having the largest touched area and the selection unit 72 receives a notification of the detection result is adopted, it is possible to obtain the same effects as above.

As described above, the user can select the target information when touching the plural sections, and it is not necessary for the user to be careful in avoiding other sections as well as in touching a specific section. As a result, since a frequency of incorrect input can be reduced and an input operation time can be shortened, a load put on the hand and the finger used for user's operation is lightened and comfortable operation becomes possible with the lightened mental and physical load.

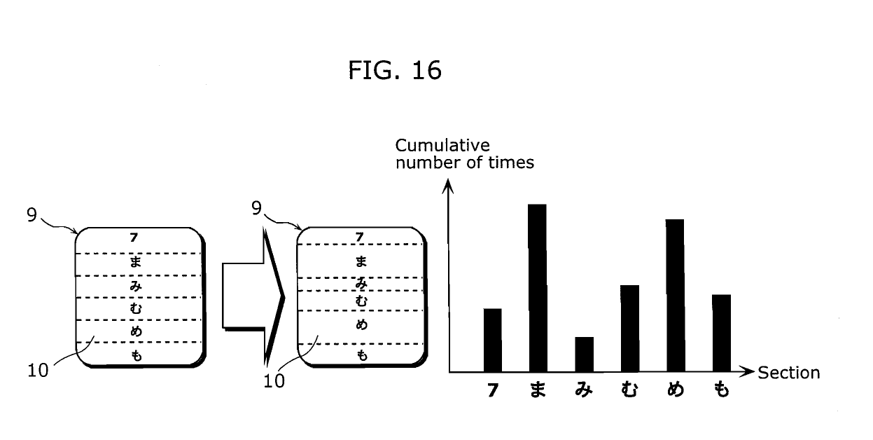

FIG. 16 is a view showing a change of ranges of each section 10 assigned on the input key 9 in the input device 1 according to the first embodiment of the present invention. As shown in FIG. 16, a cumulative number of times information associated with each section 10 is determined as input information is stored, and an area in accordance with the cumulative number of times may be assigned to each section 10. Such change of assigned ranges can be realized with a change of the above mentioned association table T content. When the association table T content is changed as stated, a LCD display content on the input key 9 is changed likewise. Since [symbol] and [symbol] are in order of descending cumulative number of times, an area assigned to each section gets smaller in the same order. This way, it is possible to set the sections 10 to suit the user characteristics.

Note that the ranges of each section 10 assigned are not necessarily based on the cumulative number of times. For example, an area of each section may be assigned by other means, such as based on a value corresponding to a probability of estimating a next character from a context of sentence being inputted.

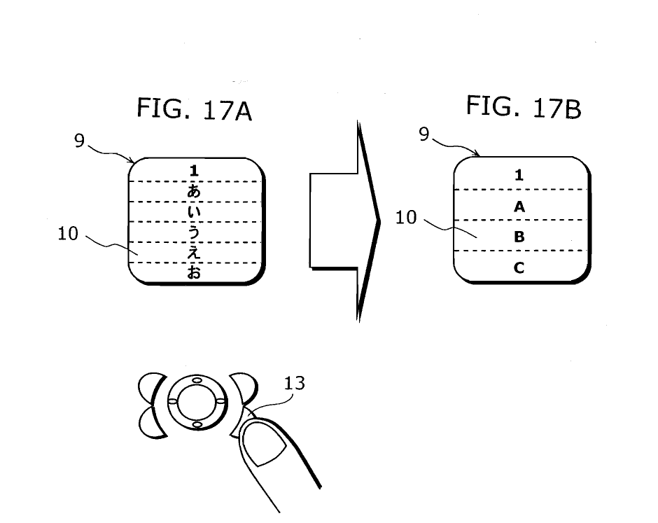

FIGS. 17A and 17B are views showing a change of information to be inputted in the input device 1 according to the first embodiment of the present invention. The input device 1 includes the information input switch key 13 and can sequentially switch to a hiragana input mode, a katakana input mode, and an alphabet input mode when a user presses the information input switch key 13. Such switching can be realized by changing the above mentioned association table T content. In this case, along with the change of the association table T content, a LCD display content on the input key 9 is changed likewise.

As shown in FIG. 17A, when each section 10 on the input key 9 is associated with a numeral or a hiragana character (the Japanese alphabet), the information input switch key 13 is pressed. At this time, the ranges of the sections 10 assigned on the input key are changed, and each section 10 is associated with “A,” “B,” or “C” as shown in FIG. 17B. Accordingly, it is possible to set the hiragana input mode, the katakana input mode, and the alphabet input mode without increasing the number of the input key 9, which allows more information to be inputted.

As the above description depicts, the plural sections are assigned on the input key 9 in the input device 1 according to the first embodiment of the present invention, and each of which is associated with the predetermined character-related information or the predetermined function information. When the input key 9 is touched by the user, information associated with a section is displayed. This way, with the information displayed, a simple operation of pressing the input key 9 once allows an input of information.

Put another way, with the input device 1 according to the first embodiment of the present invention, even if the number of pressing a key is decreased, an input efficiency does not get drastically lowered unlike before. More specifically, since sliding a user's finger on an input key 9 enables the user to select the target information from among the plural pieces of information and the selected information can be determined by pressing the input key 9 only once, it is possible to decrease the number of pressing the key.

Furthermore, since information assigned is displayed for each section of the input key 9, in the case where the first character is inputted, it is possible to easily find an input key 9 displaying the character. In particular, in the case where only one character is inputted, although an input efficiency gets drastically lowered according to the related art, this problem does not occur in the input device 1 according to the first embodiment of the present invention.

In addition, since an input key of a push-type is adopted for the input key 9, a character and the like can be inputted by an easy operation of pressing the input key 9. That is to say, the input key of the push-type has two properties: a direction to which the input key is pressed is deep; and it is not possible to physically press the input key beyond a certain depth. These properties are common among input keys of the push-type, and the user can immediately recognize that a character and the like can be already inputted when the user cannot physically press anymore.

As described above, it is possible to select the predetermined information among the plural pieces of information without requiring a careful fingertip operation on an input key, and it is possible to determine input information by pressing an input key once. As a result, a load put on the hand and the finger used for the user's operation is lightened, and comfortable operation becomes possible with the lightened mental and physical load.

Moreover, even if any section of any input key is touched by the user, the user can initially select the information determined in the previous operation. For this reason, in the case where the user wants to input information that is the same as the information determined in the past, since it is possible to determine the information only by pressing an input key without sliding a user's finger on the input key, an operation load put on the user can be lightened.

Furthermore, even if any section of any input key is touched by the user, the information selected in the previous operation can be selected initially. For this reason, the user does not need to try an information search again, which lightens a load put on the user.

The user can also select target information when touching plural sections. Accordingly, it is not necessary for the user to be careful in avoiding other sections as well as in touching a specific section. As a result, a frequency of incorrect input can be reduced, and an input operation time can be shortened.

In addition, since the ranges of each section assigned on the input key are changed based on the number of times inputted in the past, it is possible to set the sections to suit the user characteristics.

Note that although a configuration of the input key 9 is arranged in a 3×4 matrix, other key configurations may be employed.

Although FIG. 17 illustrates “the information input switch key 13” for sequentially switching from the hiragana input mode, the katakana input mode, and to the alphabet input mode, objects switched by the switching key 13 are not specifically limited. In other words, instead of “the information input switch key 13,” “a function switch key 13” for switching various functions of the input device 1 may be adopted. The various functions of the input device 1, for example, include an “e-mail” function for sending/receiving e-mail, a “web” function for browsing a web page, a “setting” function for changing setting information within the input device 1, and a “camera” function for starting a camera mounted on the input device 1. Switching such functions can be also certainly realized by changing the above mentioned association table T content.

Although the information selected by the selection unit 72 is to be determined as the input information when the press detection unit 74 detects that the input key 9 is pressed, the present invention is not limited by this. That is to say, the information selected by the selection unit 72 may be determined as the input information when the press detection unit 74 detects that the input key 9 is released from being pressed. In this case, when the user presses the input key 9, a shift to a selection mode (a mode allowing target information to be selected from plural pieces of information) is to take place. This enables the user to select the target information from among the plural pieces of information by only sliding a user's finger on the input key 9 pressed and to determine the selected information by releasing the input key 9 from being pressed (i.e., by taking the finger off from the input key 9). Even with this input mode, a simple operation of pressing the input key 9 once allows an input of information, and it is possible to obtain the same effects as above.

Although the description here is based on the assumption that plural input keys 9 include a common selected information storage unit 73 and a common determined information storage unit 76, each input key 9 may include the selected information storage unit 73 and the determined information storage unit 76. In the case where each input key 9 includes the selected information storage unit 73 and the determined information storage unit 76, it is possible to obtain special effects as described below.

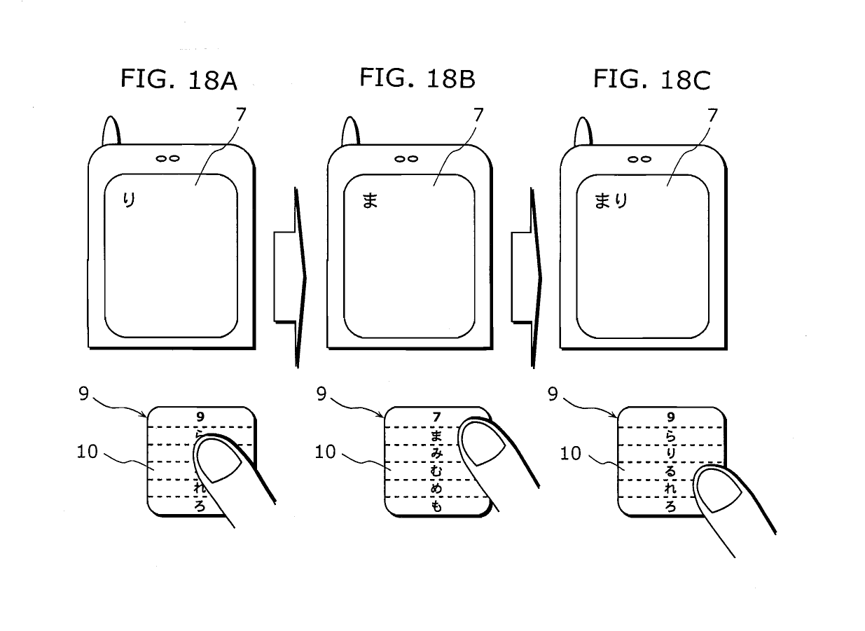

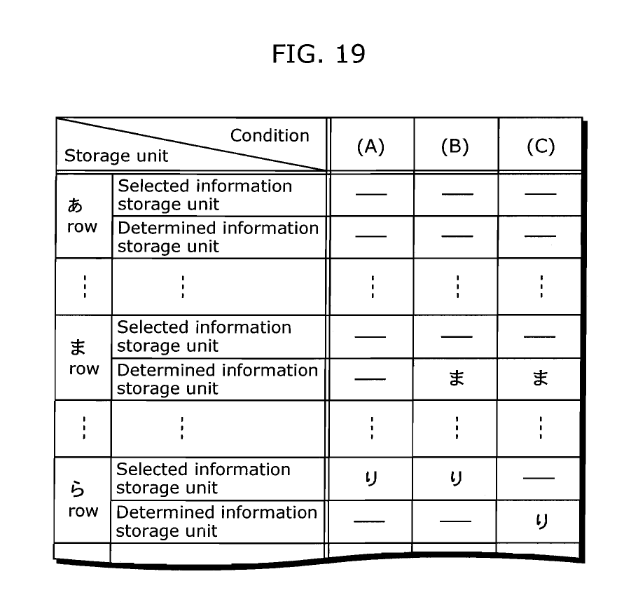

FIGS. 18A, 18B, and 18C are views, and each of which shows an input operation by a user using the input device 1 that includes the selected information storage unit 73 and determined information storage unit 76 for every input key 9. As shown in FIGS. 18A, 18B, and 18C, in the case where the user inputs characters [symbol] it is assumed that the user accidentally touches an input key 9 to which the [symbol] row instead of the [symbol] row is assigned.

In this case, the user selects the character [symbol] by sliding the finger on the input key 9 to which the [symbol] row is assigned without touching the input key 9 to which the [symbol] row is assigned (FIG. 18A). As a result, the character [symbol] is displayed on the display unit 7.

Next, the user determines the character [symbol] by touching the input key 9 to which the [symbol] row is assigned (FIG. 18B). To be more precise, the user slides the finger on the input key 9 to which the [symbol] row is assigned, selects the character [symbol] and presses the input key 9. As a result, the character [symbol] instead of the character [symbol] is displayed on the display unit 7.

After that, when the user touches the input key 9 to which the [symbol] row is assigned, the character [symbol] is selected. At this time, the character [symbol] is selected when the user touches any section of the input key 9 to which the [symbol] row is assigned (to be described later), the characters [symbol] are displayed on the display unit 7. In this condition, when the user presses the input key 9, the character [symbol] is determined. Consequently, the characters [symbol] are to be determined (FIG. 18C).

FIG. 19 is a chart showing transitions of information to be stored in the selected information storage unit 73 and the determined information storage unit 76. The description here is based on the assumption that the user inputs the above mentioned characters [symbol] Conditions (A), (B), and (C) in FIG. 19 are respectively equivalent to FIGS. 18A, 18B, and 18C, and “−” in FIG. 19 denotes that information is not stored.

First, as shown in FIG. 18A, when the user selects the character [symbol] by sliding a user's finger on the input key 9 to which the [symbol] row is assigned, the character [symbol] is stored in the selected information storage unit 73 that is included in the input key 9 to which the [symbol] row is assigned (hereinafter, “for the [symbol] row,” and the same applies to other rows).

Next, as shown in FIG. 18B, when the user selects the character [symbol] by touching the input key 9 to which the [symbol] row is assigned, the character [symbol] is stored in a determined information storage unit 76 for the [symbol] row. There is certainly a step for selecting the character [symbol] in prior to determining the character [symbol] Although the character [symbol] is stored in the determined information storage unit 76 for the [symbol] row, illustration is not given here.

After that, as FIG. 18C shows, when the user touches the input key 9 for the [symbol] row, the character [symbol] stored in a selected information storage unit 73 for the [symbol] row is selected. In this condition, when the user presses the input key 9, the character [symbol] is determined.

As described above, according to a configuration in which each input key 9 includes the selected information storage unit 73, touching any section of an input key 9 enables the user to initially select the information previously selected with the input key 9. Accordingly, even in the case where the user accidentally touches other input key 9, there is an effect that an input efficiency is not lowered. Further, even in the case where the user takes a user's finger off from the input key 9 with the target information selected by sliding the finger, there is an effect that whichever section the user presses, pressing the input key 9 from which the user takes the finger off enables the user to select the previously selected information.

On the other hand, according to a configuration in which each input key 9 includes the determined information storage unit 76, touching any section of an input key 9 enables the user to initially determine the information previously selected with the input key 9. In view of a previous example, at the time when the user finishes inputting the characters [symbol] the character [symbol] is stored in the determined information storage unit 76 for the [symbol] row, and the character [symbol] is stored in the determined information storage unit 76 for the [symbol] row. Consequently, in the case where the user wants to input the characters [symbol] successively, the user simply presses the input key 9 to which the [symbol] row is assigned and the input key 9 to which the [symbol] row is assigned.

Such function is effective in frequently inputting specific information. For example, in the case where only “.” among numerous symbols is frequently inputted, it is possible to use the specific input key 9 as the input key 9 for “.”. In the case where “/” is frequently inputted in addition to “.”, these symbols may be assigned to different input keys 9. This way, not only is it possible to use the specific input key 9 as the input key 9 for “.” but also it is possible to use other specific input key 9 as the input key 9 for “/.”

### Second Embodiment

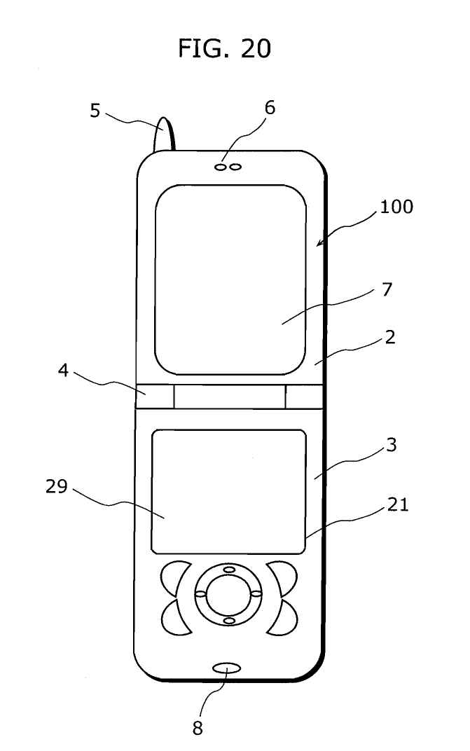

What differs between a second embodiment and the first embodiment is mainly described with reference to the FIGS. 20 to 25C. Note that the same numerical reference is used for the same component in the first embodiment, and is not described.

FIG. 20 is an external view of a mobile terminal 100 including an input device 21 according to the second embodiment of the present invention. The mobile terminal 100 is the same as described in the first embodiment, except a configuration of the input device 21.

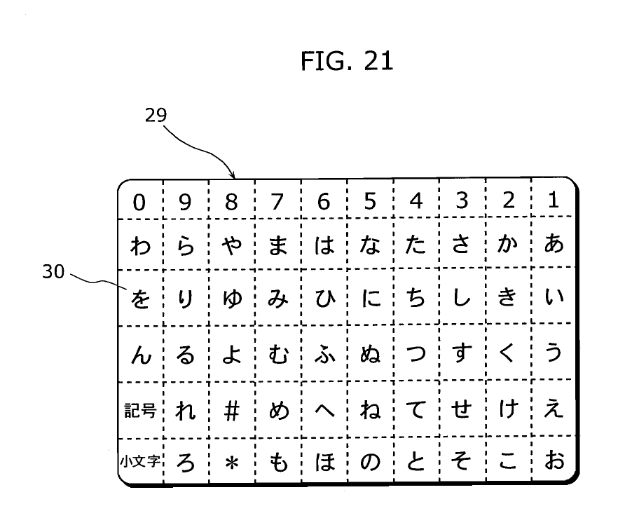

FIG. 21 is a diagram showing the configuration of the input device 21 according to the second embodiment of the present invention. The input device 21 includes an input key 29. Sections 30 are arranged in a matrix on the input key 29, and each section is matched with a numeral, a symbol, or a hiragana character. On the input key 29 is provided with a capacitive touch sensor that can detect which section of the input key 29 is touched by a user. For this reason, when the user slides a user's finger on any input key 29, the touch sensor on the input key 29 is activated so as to detect which information matched with each section 30 on the input key 29 is selected.

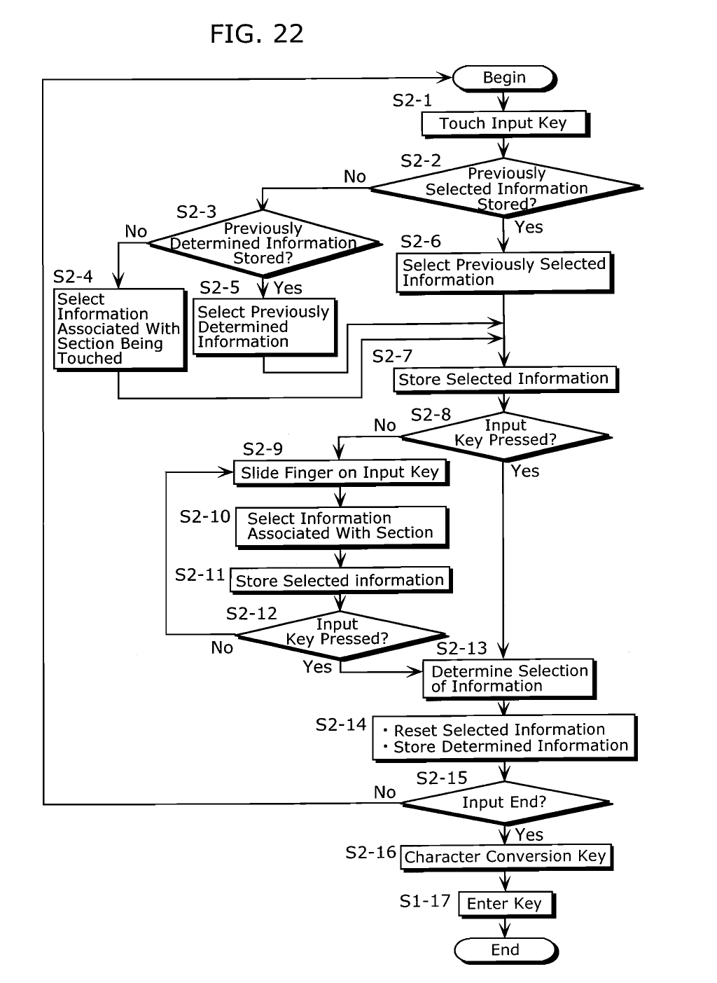

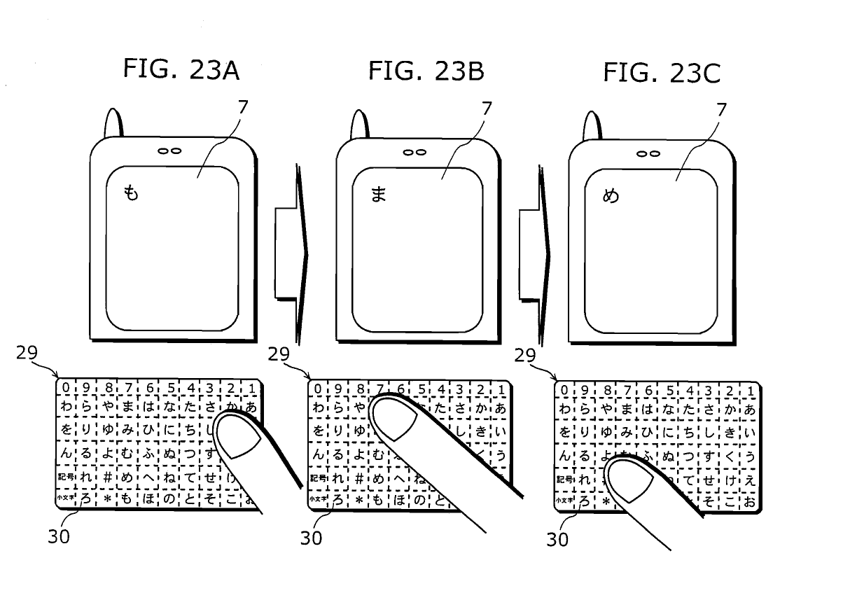

FIG. 22 is a flow chart showing operations of the input device 21 according to the second embodiment of the present invention. FIGS. 23A to 25C are views, and each of which shows an input operation by a user for the mobile terminal 100 including the input device 21 according to the second embodiment of the present invention and an operation procedure compliant with the flow chart in FIG. 22.

Hereinafter, operations of the input device 21 according to the second embodiment of the present invention are described with reference to FIGS. 22 to 25C. Note that the input device 21 includes, in addition to the input key 29, a character conversion key 11 and an enter key 12.

When any input key 29 is touched by the user (S2-1 in FIG. 22), the selection unit 72 determines whether information selected in a previous operation is stored in the selected information storage unit 73 (S2-2 in FIG. 22). “Information selected in a previous operation” is information selected by sliding the finger on the input key 29 and denotes information not determined by pressing the input key 29. In other words, in the case where the user takes the finger off from the input key 29 in the middle of selecting information, information that is associated with a section touched right before the user takes the finger off is stored in the selected information storage unit 73.

With the selected information storage unit 73, even if any section of any input key 29 is touched by the user, the information selected in the previous operation can be selected initially. For this reason, the user does not need to try an information search again, which lightens a load put on the user. The description here proceeds on the assumption that information is not stored in the selected information storage unit 73 (S2-2: No in FIG. 22).

In the case where the information selected in the previous operation is not stored in the selected information storage unit 73, the selection unit 72 determines whether information determined in a previous operation is stored in the determined information storage unit 76 (S2-3 in FIG. 22). “Information determined in a previous operation” is information selected by sliding the finger on the input key 29 and denotes information determined by pressing the input key 29. That is to say, in the case where the input of information is determined by pressing the input key 29, the information determined is stored in the determined information storage unit 76.

As shown in FIG. 23A, in the case where a character determined in a previous operation is stored in the determined information storage unit 76 (S2-3: Yes in FIG. 22), the character [symbol] determined at a previous time is selected by the selection unit 72 (S2-5 in FIG. 22), stored in the selected information storage unit 73 (S2-7 in FIG. 22), and additionally displayed on the display unit 7. At this time, in the case where the user wants to input the character [symbol] it is possible to just press the input key 29 to determine the character [symbol] as the input information (S2-8: Yes in FIG. 22).

With the determined information storage unit 76, even if any section of any input key 29 is touched by the user, the information determined in the previous operation can be selected initially. For this reason, the user does not need to slide the finger on the input key 29, which can lighten the operation load and shorten the input operation time.

Note that in the case where the information determined in the previous operation is not stored in the determined information storage unit 76 (S2-3: No in FIG. 22), information that is associated with a section touched by the user is selected by the selection unit 72 (S2-4 in FIG. 22), stored in the selected information storage unit 73 (S2-7 in FIG. 22), and additionally displayed on the display unit 7.

With the character [symbol] selected, as shown in FIG. 23B, when the user touches a section 30 of [symbol] assigned on the input key 29 (S2-9 in FIG. 22) without pressing the input key 29 (S2-8: No in FIG. 22), the character [symbol] is selected by the selection unit 72 (S2-10 in FIG. 22), stored in the selected information storage unit 73 (S2-11 in FIG. 22), and additionally displayed on the display unit 7.

In this condition, as shown in FIG. 12C, when the user slides the finger to other section (for example, the section of [symbol] without pressing the input key 29 (S2-12: No in FIG. 22), the character [symbol] by the selection unit 72 (S2-10 in FIG. 22), stored in the selected information storage unit 73 (S2-11 in FIG. 22), and additionally displayed on the display unit 7.

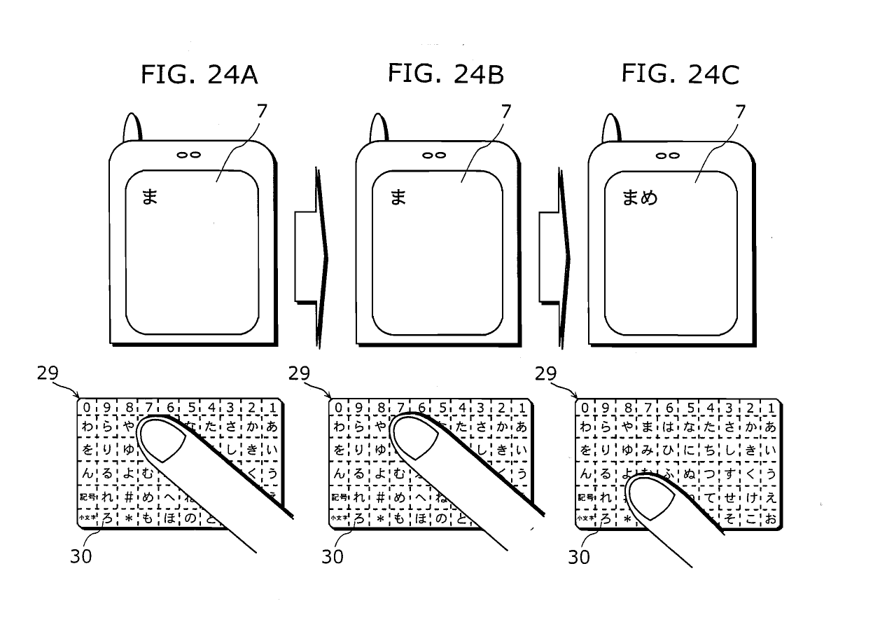

Furthermore, as shown in FIG. 24A, when the user presses the input key 29 while touching the section 30 to which the character [symbol] is assigned on the input key 29 (S2-8: Yes in FIG. 22), as shown in FIG. 24B, the character [symbol] is determined as the input information (S2-13 in FIG. 11) and stored in the determined information storage unit 76 (S2-14 in FIG. 22). With the character [symbol] displayed on the display unit 7, an input of next information becomes possible.

At this time, the selection unit 72 deletes the information stored in the selected information storage unit 73 by resetting. Consequently, in the case where the user continuously inputs a character (S2-15: No in FIG. 22), when the user touches again the input key 29 with which an input has been determined in a previous operation (S2-1 in FIG. 22), information determined in a previous operation is selected initially (S2-3 in FIG. 22) since information is not stored in the selected information storage unit 73 (S2-3: No in FIG. 22). Therefore, the user can determine an input of information without sliding the finger on the input key 29, which can lighten the operation load and shorten the input operation time.

After the character [symbol] is determined, in the case where the user further continues an input of character with the same input key 29 without ending the input of character (S2-15: No in FIG. 22), the user slides the finger to the section to which the character [symbol] is assigned in that condition (S2-9 in FIG. 22). Accordingly, as shown in FIG. 24C, with the character [symbol] displayed on the display unit 7, the character [symbol] is selected by the selection unit 72 (S2-10 in FIG. 22), stored in the selected information storage unit 73 (S2-11 in FIG. 22), and additionally displayed on the display unit 7.

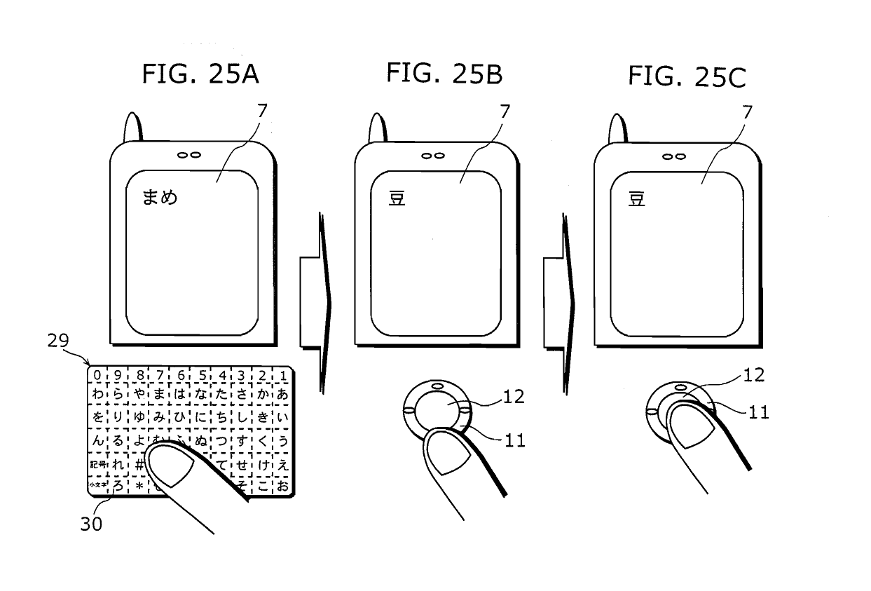

Moreover, as shown in FIG. 25A, with the character [symbol] displayed, when the user presses the input key 29 (S2-12: Yes in FIG. 22), the character [symbol] is determined as the input information (S2-13 in FIG. 22) and stored in the determined information storage unit 76 (S2-14 in FIG. 22). In addition, characters [symbol] remain displayed on the display unit 7. In this condition, when the user ends an input of character (S2-15: Yes in FIG. 22) and presses the character conversion key 11 (S2-16 in FIG. 22) as shown in FIG. 25B, character conversion candidates of [symbol] are displayed. Consequently, when the user selects a desired character among the character conversion candidates and presses the enter key 12 (S2-17 in FIG. 22) as shown in FIG. 25C, the input of character [symbol] gets completed.

As described above, only sliding the finger on the input key enables the user to reach target information, and it becomes possible for the user to press the input key only once to determine the information as the input information.

As the above description depicts, with the input device 21 according to the second embodiment of the present invention, only sliding the finger on an input key 29 enables the user to reach the target information and to determine all information as the input information with the input key 29. For this reason, in addition to the effects of the above mentioned first embodiment, it is possible to obtain an effect that a time and an effort for moving the finger to other input key can be eliminated. As a result, the load put on the hand and the finger used for user's operation is lightened and comfortable operation becomes possible with the lightened mental and physical load. Additionally, even if any section of the input key is touched by the user, the user can initially select information determined in a previous operation. Consequently, in the case where the user wants to input information that is the same as information determined in the past, since it is possible to determine the information only by pressing the input key without sliding the finger on the input key, an operation load put on the user can be lightened.

Moreover, even if the user touches any section of any input key 9, the information selected in the previous operation can be selected initially. For this reason, the user does not need to try an information search again, which lightens a load put on the user.

Furthermore, similar to the first embodiment, a configuration in which information associated with each section is displayed on an input key is adopted in the second embodiment. As a result, it is not necessary to display information selected on a display unit, and the user can easily recognize target information from a display on the input key before touching the input key. In particular, in the case where information is two-dimensionally arranged in rows and columns, when the display is on the input key, it is useful for the user to easily remember a position of information.

### Third Embodiment

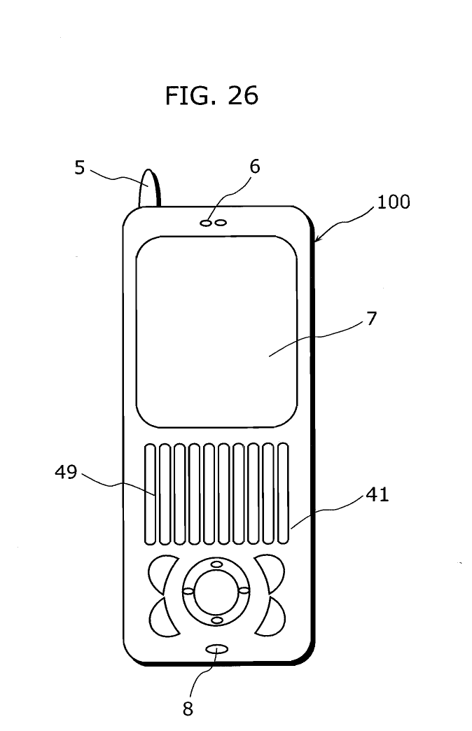

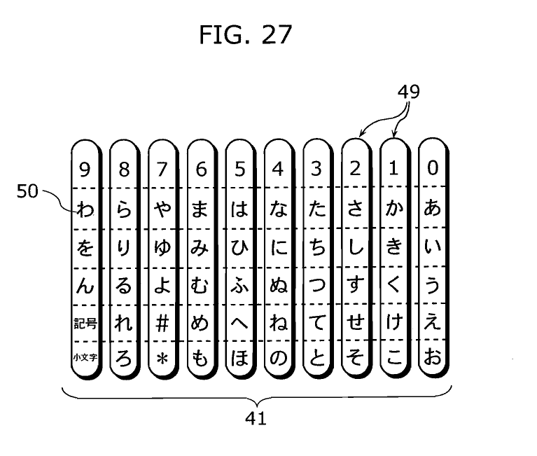

What differs between a third embodiment and the first and second embodiments is mainly described with reference to FIGS. 26 and 27. Note that the same numerical reference is used for the same component in the first and second embodiments, and is not described.

FIG. 26 is an external view of a mobile terminal 100 including an input device 41 according to the third embodiment of the present invention. The mobile terminal 100 is the same as described in the first and second embodiments, except a configuration of the input device 41.

FIG. 27 is a diagram showing the configuration of the input device 41 according to the third embodiment of the present invention. The input device 41 includes plural input keys 49. The input keys 49 are arranged in a line to a short side of the mobile terminal 100. In addition, sections 50 are linearly assigned on each input key 49, and each section is associated with predetermined character-related information or predetermined function information. Further, on each input key 49 is provided with a capacitive touch sensor that can detect which section of the input key 49 is touched by a user. For this reason, when the user slides a user's finger on any input key 49, the touch sensor on the input key 49 is activated so as to detect which information associated with each section on the input key 49 is selected.

An operation of the mobile terminal including the input device 41 according to the third embodiment is the same as that of the input device having the plural input keys according to the first embodiment.

As the above description depicts, with the input device 41 according to the third embodiment of the present invention, the user only needs to move the user's finger horizontally to select the input key 49 and to slide the finger vertically to perform a character selection operation. Accordingly, in addition to the effects of the first embodiment, it is possible to obtain an effect that a simpler input key arrangement which is easy for the user to understand can be realized. As a result, a load put on a hand and a finger used for operation can be lightened, and comfortable operation becomes possible with the lightened mental and physical load.

Moreover, similar to the first embodiment, a configuration in which information associated with each section is displayed on an input key is adopted in the third embodiment. Consequently, it is not necessary to display selected information on a display unit 7, and the user can easily recognize target information from a display on the input key before touching the input key.

Note that although the input keys 49 are arranged in a line to a short side of the mobile terminal 100, other arrangements are certainly acceptable. For example, input keys may be arranged in a line to a long side of the mobile terminal 100, and the input keys arranged in a line to a long side of the mobile terminal and the input keys arranged in a line to a short side of the mobile terminal may be combined.

In addition, although the description here is based on the assumption that plural input keys 49 include a common selected information storage unit 73 and a common determined information storage unit 76, similar to the first embodiment, each input key 49 may include the selected information storage unit 73 and the determined information storage unit 76. A special effect in this case is not described here as it is the same as in the first embodiment.

### Fourth Embodiment

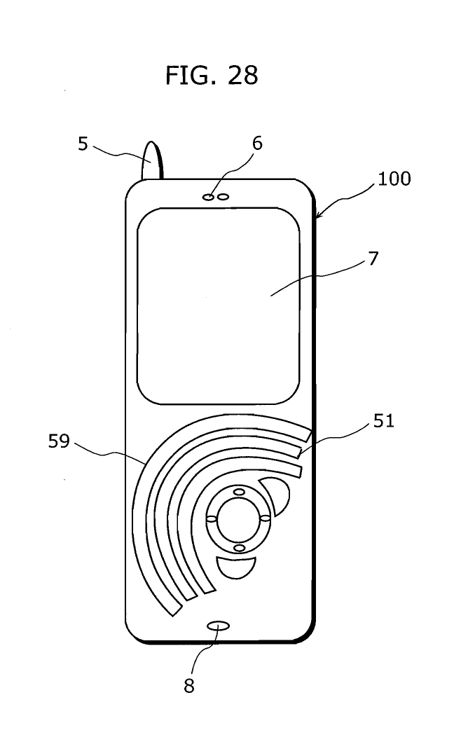

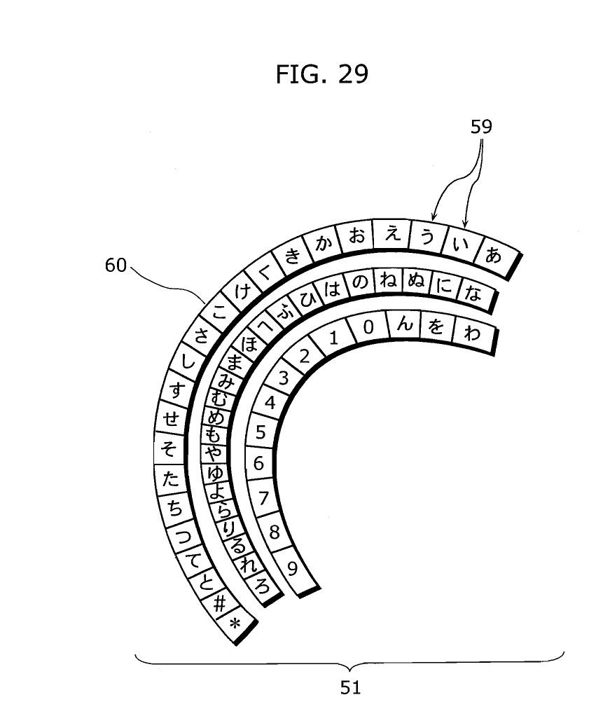

What differs between a fourth embodiment and the first, second, and third embodiments is mainly described with reference to FIGS. 28 and 29. Note that the same numerical reference is used for the same component in the first, second, and third embodiments, and is not described.

FIG. 28 is an external view of a mobile terminal 100 including an input device 51 according to the fourth embodiment of the present invention. The mobile terminal 100 is the same as described in the first, second, and third embodiments, except a configuration of the input device 51.

FIG. 29 is a diagram showing the configuration of the input device 51 according to the fourth embodiment of the present invention. The input device 51 includes plural input keys 59. The input keys 59 are arranged in a semi-arc to the mobile terminal 100. In addition, sections 60 are assigned on each input key 59, and each section is associated with predetermined character-related information or predetermined function information. Further, on each input key 59 is provided with a capacitive touch sensor that can detect which section of the input key 59 is touched by a user. For this reason, when the user slides a user's finger on any input key 59, the touch sensor on the input key 59 is activated so as to detect which information associated with each section on the input key 59 is selected.

An operation of the mobile terminal including the input device 51 according to the fourth embodiment is the same as that of the input device having the plural input keys according to the first embodiment.

As the above description depicts, with the input device 51 according to the fourth embodiment of the present invention, since the input keys 59 are arranged substantially in arch form, in addition to the effects of the first embodiment, it is possible to obtain an effect that an operation suitable for a range of movement of a user's hand and finger, especially a range of movement of a user's thumb, becomes possible. As a result, a load put on a hand and a finger used for operation can be lightened, and comfortable operation becomes possible with a lightened mental and physical load.

Note that although the input keys 59 are arranged substantially in arc form, other arrangements are certainly acceptable. For example, input keys may be arranged in a circle or in an oval, and the input keys arranged linearly and the input keys arranged in an arc may be combined. In addition, the arc does not necessarily have a single center. The arc may be combined with a line, and circles having plural centers may be combined.

Furthermore, although the description here is based on the assumption that plural input keys 59 include a common selected information storage unit 73 and a common determined information storage unit 76, similar to the first embodiment, each input key 59 may include the selected information storage unit 73 and the determined information storage unit 76. A special effect in this case is not described here as it is the same as in the first embodiment.

Although a capacitive touch sensor is adopted in the above description, the present invention is not limited by this. For example, an electromagnetic induction type, a resistive-sheet type, or an infrared type touch sensor, an optical sensor, a pressure sensor and the like may suffice for determining which section is touched by the user.

Although the above mentioned section detection unit 70 detects a section having the largest touched area, the present invention is not limited by this. That is to say, in the case where the pressure sensor instead of the capacitive touch sensor is adopted, the section having the largest pressure may be detected.

Although the input keys according to the present invention are preferably configured by hardware, taking a touch panel for example, they may be configured by software. In other words, the input keys described according to the fourth embodiment may be a configuration in which plural soft keys are assigned to a single physical key. Further, it is designed that touching a soft key selects information and pressing the physical key determines the information. Therefore, in the case where the input keys are configured only by the soft keys, a mechanism equivalent to pressing the physical key (a mechanism for determination selected information as the input information) needs to be adopted separately. Although the mechanism is not specifically limited, for example, after a predetermined time (e.g. two seconds) has passed since information was selected, the selected information may be determined as the input information. This way, it is also possible to obtain the above mentioned same effects through a simple operation of touching once a section associated with desired information.

A display unit according to the present invention not only provides information to the user, but also may include a means to provide the information with audio and light.

A way to assign sections on the input key according to the present invention is not necessarily limited to the assignment shown in the fourth embodiment, and other ways to assign are certainly acceptable.

The character-related information according to the above embodiments is a generic term for characters, numerals, and symbols. The characters include not only Japanese hiragana and katakana characters and Chinese characters, but also the Roman alphabet, the Korean alphabet, and Chinese. That is to say, the characters may be the symbols used for mutual human communication. Moreover, the numerals include not only the Arabic numeral, but also the Roman numeral and the Chinese numeral. Furthermore, the symbols include not only symbols, such as “!”, “?”, punctuation marks and the like, used along with a character input, but also emoticons and icons.

According to the above embodiment, although an input with Japanese is mainly described, information to be inputted may certainly be other linguistic information. In other words, when information in the association table T in FIG. 7 is replaced with other linguistic information, an input with Chinese, English, German, French and the like can be realized by the same operation.

The information in the above mentioned association table T is not limited to the character-related information or the function information, and may be other information. For example, when music information, television program information and the like are associated in the association table T, the user slides the finger on an input key to select a music or a television program, and pressing the input key enables the user to determine selection of a desired music or television program.

Association between sections on the input key and information in the present invention is not necessarily limited to what is shown in the above embodiment, and other ways for associating are acceptable. For example, although sections in a matrix-like form are associated with the Japanese hiragana characters, information to be associated may be information to be frequently inputted, and may be associated with, for instance, an alphabet and a numeral.

In the above description, although the configuration in which the present invention is applied to the mobile terminal is illustrated, a scope of application of the present invention is not limited by this. That is to say, the present invention can be applied to a mobile device, such as a remote controller and a game console, which a user holds in and performs an input operation for with one hand.

### INDUSTRIAL APPLICABILITY

The input device in the present invention is useful as a mobile phone, a remote controller, a game console and the like on which an input efficiency does not get drastically lowered even if the number of pressing a key is reduced.

1. An input device for inputting information, said input device comprising:
an input key of a push-type, which has predetermined sections on each of which one of predetermined character-related information and predetermined function information is displayed;
an association storage unit operable to store each of the predetermined sections of said input key in association with one of the predetermined character-related information and the predetermined function information;
a section detection unit operable to detect which section of said input key is touched by an object;
a selection unit operable to select, from among the information stored in said association storage unit, information that is associated with the section detected by said section detection unit, as input information;
a press detection unit operable to detect that said input key is pressed or released from being pressed; and
a determination unit operable to determine the information selected by said selection unit as the input information, when said press detection unit detects that said input key is pressed or released from being pressed.

2. The input device according to claim 1, further comprising
a determined information storage unit operable to store the information determined by said determination unit,
wherein, when said input key is touched by the object, said selection unit is operable to select, as the input information, the information stored in said determined information storage unit.

3. The input device according to claim 1, further comprising
a selected information storage unit operable to store the information selected by said selection unit,
wherein, when said input key is touched by the object, said selection unit is operable to select, as the input information, the information stored in said determined information storage unit.

4. The input device according to claim 1, further comprising
a determined information storage unit provided for each said input key, operable to store the information determined by said determination unit,
wherein, when an input key is touched by the object, said selection unit is operable to select, as the input information, the information stored in said determined information storage unit for the input key.

5. The input device according to claim 1, further comprising
a selected information storage unit provided for each said input key, operable to store the information selected by said selection unit,
wherein, when an input key is touched by the object, said selection unit is operable to select, as the input information, the information stored in said selected information storage unit for the input key.

6. The input device according to claim 1,
wherein, when said section detection unit detects a plurality of sections, said selection unit is operable to select, as the input information, the information associated with a section having a largest touched area among sections detected by said section detection unit.

7. The input device according to claim 1,
wherein, when said section detection unit detects a plurality of sections, said section detection unit is operable to notify said selection unit of the section having a largest touched area.

8. The input device according to claim 1, further comprising
a change unit for changing the information stored in said association storage unit.

9. The input device according to claim 8,
wherein, the larger the number of times information is determined by said determination unit, the more said change unit is operable to increase an area of the section associated with the information.

10. The input device according to claim 1,
wherein said input key is plural in number.

11. The input device according to claim 10,
wherein said input keys are arranged in a m×n matrix.

12. The input device according to claim 10,
wherein said input keys form a numeric keypad.

13. The input device according to claim 10,
wherein said input keys are arranged substantially parallel.

14. The input device according to claim 10,
wherein said input keys are arranged substantially in arc form.

15. The input device according to claim 10,
wherein said association storage unit is operable to associate each of a plurality of the sections arranged substantially linearly with one of the predetermined character-related information and the predetermined function information.

16. The input device according to claim 1,
wherein said input key is one in number.

17. The input device according to claim 16,
wherein said association storage unit is operable to associate one of a plurality of the sections substantially in a matrix with one of the predetermined character-related information and the predetermined function information.

18. A mobile terminal with which information can be inputted, said mobile terminal comprising:
an input key of a push-type, which has predetermined sections on each of which one of predetermined character-related information and predetermined function information is displayed;
an association storage unit operable to store the predetermined sections of said input key in association with one of the predetermined character-related information and the predetermined function information;
a section detection unit operable to detect which section of said input key is touched by an object;
a selection unit operable to select, from among the information stored in said association storage unit, information that is associated with a section detected by said section detection unit, as input information;
a press detection unit operable to detect that said input key is pressed or released from being pressed; and
a determination unit operable to determine the information selected by said selection unit as the input information, when said press detection unit detects that said input key is pressed or released from being pressed.

19. An input method for inputting information, said input method comprising steps of:
detecting which one of predetermined sections of an input key, on each of which one of predetermined character-related information and predetermined function information is displayed, is touched by an object;
selecting, from among one of the predetermined character-related information and the predetermined function information that is associated with the predetermined sections of said input key, information that is associated with the section detected in said detecting, as input information;
detecting that said input key is pressed or released from being pressed; and
determining the information selected in said selecting as the input information, when it is detected that said input key is pressed or released from being pressed in said press detecting.
